(19) United States
(12) Patent Application Publication
(10) Pub. No.: US 2023/0225133 A1
(43) Pub. Date: Jul. 13, 2023

(54) SEMICONDUCTOR STORAGE DEVICE AND METHOD OF MANUFACTURING SEMICONDUCTOR STORAGE DEVICE

(71) Applicant: SONY SEMICONDUCTOR SOLUTIONS CORPORATION, KANAGAWA (JP)

(72) Inventor: JUN OKUNO, KANAGAWA (JP)

(21) Appl. No.: 18/000,794

(22) PCT Filed: Apr. 30, 2021
(86) PCT No.: PCT/JP2021/017227

§ 371 Date: Dec. 5, 2022

(30) Foreign Application Priority Data
Jun. 11, 2020 (JP) 2020-101916

(51) Int. Cl. H10B 53/20; H10B 53/10; H10B 51/20; H10B 51/10; H01L 29/51; H01L 29/66; H01L 29/78

(52) U.S. Cl. CPC H10B 53/20; H01L 29/516; H01L 29/6684; H01L 29/78391; H10B 51/10; H10B 51/20; H10B 53/10

(57) ABSTRACT

A semiconductor storage device includes a field-effect transistor, an interlayer insulation film, a source contact, an opening, and a capacitor. The field-effect transistor is provided on a semiconductor substrate. The interlayer insulation film is provided on the semiconductor substrate. The source contact runs through the interlayer insulation film and is electrically coupled to a source of the field-effect transistor. The opening is provided in a region of the interlayer insulation film including the source contact and allows the source contact to project therein. The capacitor includes a lower electrode, a ferroelectric film, and an upper electrode. The lower electrode is provided along an inside shape of the opening. The ferroelectric film is provided on the lower electrode. The upper electrode is provided on the ferroelectric film to fill the opening.

### TECHNICAL FIELD

The present disclosure relates to a semiconductor storage device and a method of manufacturing a semiconductor storage device.

### BACKGROUND ART

Recently, development has been progressed of a FeRAM (Ferroelectric Random Access Memory) that stores data using a direction of residual polarization of a ferroelectric body. For example, proposed is a FeRAM in which memory cells each including one transistor and one ferroelectric capacitor are arranged in an array (for example, PTL 1).

### CITATION LIST

### Patent Literature

PTL 1: Japanese Unexamined Patent Application Publication No. 2019-160841

### SUMMARY OF THE INVENTION

In such a FeRAM, a size of a memory window for distinguishing between a 1-state and a 0-state of stored data depends on capacitance of a ferroelectric capacitor. Accordingly, it is desired to increase the capacitance per unit area of the ferroelectric capacitor to increase the size of the memory window, and to thereby increase operation reliability of the FeRAM.

It is therefore desirable to provide a semiconductor storage device and a method of manufacturing a semiconductor storage device that are further improved in operation reliability.

A semiconductor storage device according to an embodiment of the present disclosure includes a field-effect transistor, an interlayer insulation film, a source contact, an opening, and a capacitor. The field-effect transistor is provided on a semiconductor substrate. The interlayer insulation film is provided on the semiconductor substrate. The source contact runs through the interlayer insulation film and is electrically coupled to a source of the field-effect transistor. The opening is provided in a region of the interlayer insulation film including the source contact and allows the source contact to project therein. The capacitor includes a lower electrode, a ferroelectric film, and an upper electrode. The lower electrode is provided along an inside shape of the opening. The ferroelectric film is provided on the lower electrode. The upper electrode is provided on the ferroelectric film to fill the opening.

A method of manufacturing a semiconductor storage device according to an embodiment of the present disclosure includes: forming a field-effect transistor on a semiconductor substrate; forming an interlayer insulation film on the semiconductor substrate; forming a source contact that runs through the interlayer insulation film and is electrically coupled to a source of the field-effect transistor; forming an opening in a region of the interlayer insulation film including the source contact, the opening allowing the source contact to project therein; and forming a capacitor by stacking a lower electrode and a ferroelectric film along an inside shape of the opening and forming an upper electrode on the ferroelectric film to fill the opening.

In the semiconductor storage device and the method of manufacturing a semiconductor storage device each according to the embodiment of the present disclosure, the opening is provided in the interlayer insulation film in which the field-effect transistor is embedded, in such a manner that the source contact electrically coupled to the source of the field-effect transistor is exposed therein. The capacitor including the ferroelectric film is provided along the inside shape of the opening. Accordingly, for example, the area of the capacitor including the ferroelectric film increases, and as a result, the capacitance of the capacitor including the ferroelectric film increases.

### BRIEF DESCRIPTION OF DRAWINGS

FIG. 1 is a circuit diagram illustrating an equivalent circuit of a semiconductor storage device according to a first embodiment of the present disclosure.

FIG. 2 is a schematic diagram illustrating a cross-sectional configuration of the semiconductor storage device according to the embodiment.

FIG. 3 is a schematic diagram illustrating a plan configuration for two memory cells of the semiconductor storage device according to the embodiment.

FIG. 4A is a cross-sectional view for describing a process of a method of manufacturing the semiconductor storage device according to the embodiment.

FIG. 4B is a cross-sectional view for describing a process of the method of manufacturing the semiconductor storage device according to the embodiment.

FIG. 4C is a cross-sectional view for describing a process of the method of manufacturing the semiconductor storage device according to the embodiment.

FIG. 4D is a cross-sectional view for describing a process of the method of manufacturing the semiconductor storage device according to the embodiment.

FIG. 4E is a cross-sectional view for describing a process of the method of manufacturing the semiconductor storage device according to the embodiment.

FIG. 4F is a cross-sectional view for describing a process of the method of manufacturing the semiconductor storage device according to the embodiment.

FIG. 5 is a schematic diagram illustrating a cross-sectional configuration of a semiconductor storage device according to a second embodiment of the present disclosure.

FIG. 6 is a schematic diagram illustrating a plan configuration for two memory cells of the semiconductor storage device according to the embodiment.

FIG. 7A is a cross-sectional view for describing a process of a method of manufacturing the semiconductor storage device according to the embodiment.

FIG. 7B is a cross-sectional view for describing a process of the method of manufacturing the semiconductor storage device according to the embodiment.

FIG. 7C is a cross-sectional view for describing a process of the method of manufacturing the semiconductor storage device according to the embodiment.

FIG. 7D is a cross-sectional view for describing a process of the method of manufacturing the semiconductor storage device according to the embodiment.

FIG. 7E is a cross-sectional view for describing a process of the method of manufacturing the semiconductor storage device according to the embodiment.

FIG. 8 is a schematic diagram illustrating a cross-sectional configuration of a semiconductor storage device according to a third embodiment of the present disclosure.

FIG. 9 is a schematic diagram illustrating a plan configuration for two memory cells of the semiconductor storage device according to the embodiment.

FIG. 10A is a cross-sectional view for describing a process of a method of manufacturing a semiconductor storage device according to the embodiment.

FIG. 10B is a cross-sectional view for describing a process of the method of manufacturing the semiconductor storage device according to the embodiment.

FIG. 10C is a cross-sectional view for describing a process of the method of manufacturing the semiconductor storage device according to the embodiment.

FIG. 10D is a cross-sectional view for describing a process of the method of manufacturing the semiconductor storage device according to the embodiment.

FIG. 10E is a cross-sectional view for describing a process of the method of manufacturing the semiconductor storage device according to the embodiment.

FIG. 11 is a schematic diagram illustrating a cross-sectional configuration of a semiconductor storage device according to a fourth embodiment of the present disclosure.

FIG. 12 is a schematic diagram illustrating a cross-sectional configuration of a semiconductor storage device according to a fifth embodiment of the present disclosure.

FIG. 13 is a schematic diagram illustrating a plan configuration for two memory cells of the semiconductor storage device according to the embodiment.

FIG. 14 is a schematic diagram illustrating a cross-sectional configuration of a semiconductor storage device according to a sixth embodiment of the present disclosure.

FIG. 15 is a schematic diagram illustrating a cross-sectional configuration of a semiconductor storage device according to a seventh embodiment of the present disclosure.

FIG. 16 is a schematic diagram illustrating a cross-sectional configuration of a semiconductor storage device according to an eighth embodiment of the present disclosure.

FIG. 17 is a schematic diagram illustrating a cross-sectional configuration of a semiconductor storage device according to a ninth embodiment of the present disclosure.

FIG. 18A is a cross-sectional view for describing a process of a method of manufacturing the semiconductor storage device according to the embodiment.

FIG. 18B is a cross-sectional view for describing a process of the method of manufacturing the semiconductor storage device according to the embodiment.

FIG. 18C is a cross-sectional view for describing a process of the method of manufacturing the semiconductor storage device according to the embodiment.

FIG. 18D is a cross-sectional view for describing a process of the method of manufacturing the semiconductor storage device according to the embodiment.

FIG. 18E is a cross-sectional view for describing a process of the method of manufacturing the semiconductor storage device according to the embodiment.

### MODES FOR CARRYING OUT THE INVENTION

The following describes some embodiments of the present disclosure in detail with reference to the drawings. The embodiments described below are specific examples of the present disclosure, and the technology according to the present disclosure is not limited to the following embodiments. In addition, arrangements, dimensions, dimension ratios, etc. of respective components of the present disclosure are not limited to the embodiments illustrated in the respective drawings.

It is to be noted that the description is given in the following order.
1. First Embodiment
   1.1. Outline
   1.2. Configuration Example
   1.3. Manufacturing Method
2. Second Embodiment
   2.1. Configuration Example
   2.2. Manufacturing Method
3. Third Embodiment
   3.1. Configuration Example
   3.2. Manufacturing Method
4. Fourth Embodiment
5. Fifth Embodiment
6. Sixth Embodiment
7. Seventh Embodiment
8. Eighth Embodiment
9. Ninth Embodiment
   9.1. Configuration Example
   9.2. Manufacturing Method

### <1. First Embodiment>

### (1.1. Outline)

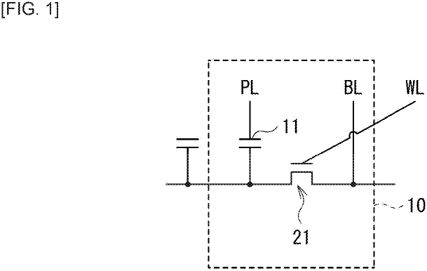

First, referring to FIG. 1, described is an outline of a semiconductor storage device according to a first embodiment of the present disclosure. FIG. 1 is a circuit diagram illustrating an equivalent circuit of the semiconductor storage device according to the present embodiment.

As illustrated in FIG. 1, a semiconductor storage device 10 according to the present embodiment includes a capacitor 11 and a transistor 21. The capacitor 11 stores data. The transistor 21 controls selection and non-selection of the capacitor 11.

The capacitor 11 is a ferroelectric capacitor including a pair of electrodes and a ferroelectric film sandwiched between the pair of electrodes. The capacitor 11 is able to store 1 bit of data using a direction of residual polarization of the ferroelectric film. The capacitor 11 is electrically coupled to a plate line PL at one of the pair of electrodes and is electrically coupled to a source of the transistor 21 at the other of the pair of electrodes.

The transistor 21 is a field-effect transistor that controls application of a voltage to the capacitor 11. The transistor 21 is electrically coupled to the other electrode of the capacitor 11 at the source and is electrically coupled to a bit line BL at a drain. Further, the transistor 21 is electrically coupled to a word line WL at a gate, and a state of a channel is controllable by an applied voltage from the word line WL.

In a case of writing data in the capacitor 11, in the semiconductor storage device 10, first, a voltage is applied to the word line WL to thereby cause the channel of the transistor 21 to transition to an on state. Thereafter, a potential is applied to each of the plate line PL and the bit line BL to thereby apply an electric field corresponding to the data to be written to the ferroelectric film of the capacitor 11. Accordingly, the semiconductor storage device 10 is able to write data in the capacitor 11 by controlling the direction of the residual polarization of the ferroelectric film of the capacitor 11 with use of an external electric field.

In contrast, in a case of reading data from the capacitor 11, in the semiconductor storage device 10, first, a voltage is applied to the word line WL to thereby cause the channel of the transistor 21 to transition to the on state. Thereafter, a predetermined potential is applied to each of the plate line PL and the bit line BL to thereby cause the polarization direction of the ferroelectric film of the capacitor 11 to transition to a predetermined direction. At this time, the magnitude of a current flowing into the capacitor 11 upon transition changes depending on the direction of the polarization of the ferroelectric film before the transition. Accordingly, the semiconductor storage device 10 is able to read the data stored in the capacitor 11 by measuring the magnitude of the current flowing into the capacitor 11.

Thus, the semiconductor storage device 10 according to the present embodiment is able to operate as a FeRAM (Ferroelectric Random Access Memory) that stores data in the capacitor 11 including the ferroelectric film.

### (1.2. Configuration Example)

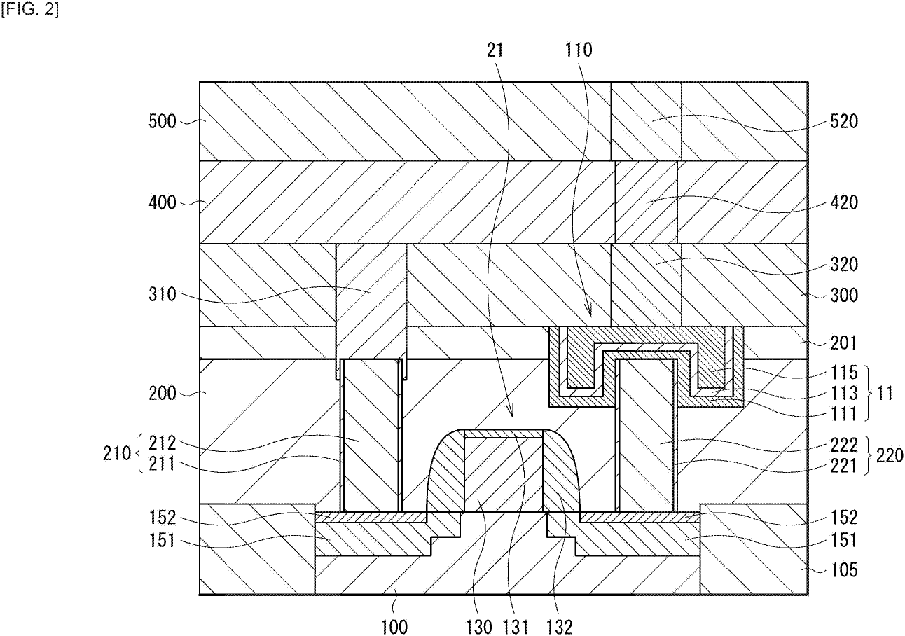

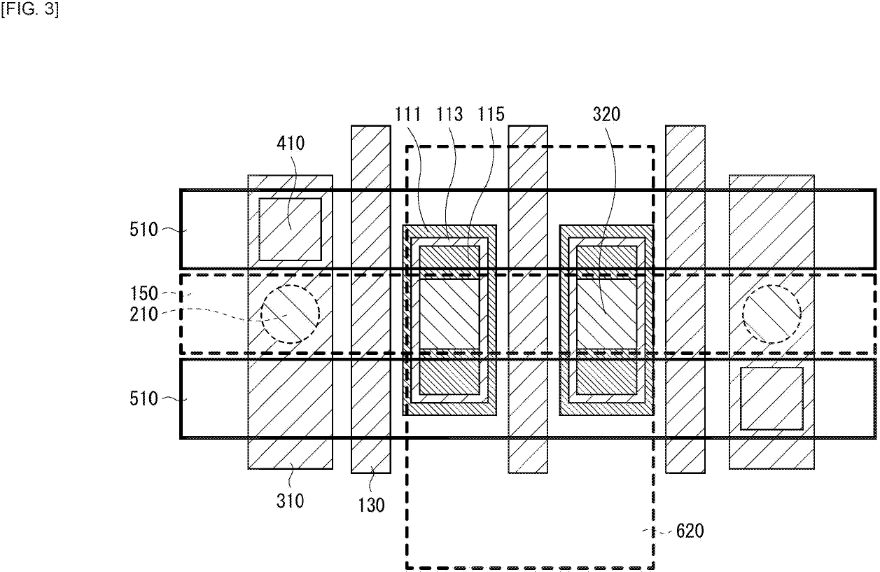

Next, referring to FIGS. 2 and 3, described is a specific configuration example of the semiconductor storage device according to the present embodiment. FIG. 2 is a schematic diagram illustrating a cross-sectional configuration of the semiconductor storage device according to the present embodiment.

Further, in the following, a “first conductivity type” refers to one of a “p-type” or an “n-type”, and a “second conductivity type” refers to the other of the “p-type” or the “n-type” different from the “first conductivity type”.

As illustrated in FIG. 2, the transistor 21 includes source or drain regions 151 provided on the semiconductor substrate 100 and a gate electrode 130 provided on the semiconductor substrate 100. The drain side of the source or drain regions 151 is electrically coupled to a drain contact 210, and the source side of the source or drain regions 151 is electrically coupled to a source contact 220.

The transistor 21 is embedded in a first interlayer insulation film 200 and a second interlayer insulation film 201. The drain contact 210 and the source contact 220 are provided to run through the first interlayer insulation film 200. The drain contact 210 is electrically coupled to a first wiring layer 310 provided in a first insulation layer 300, and the source contact 220 is electrically coupled to the capacitor 11 provided by digging the first interlayer insulation film 200 and the second interlayer insulation film 201.

The capacitor 11 includes a lower electrode 111, a ferroelectric film 113, and an upper electrode 115. The lower electrode 111 is electrically coupled to the source contact 220, and the upper electrode 115 is electrically coupled to a first wiring layer 320 provided in the first insulation layer 300. In addition, the first wiring layer 320 is electrically coupled to a second wiring layer 520 provided in a third insulation layer 500 via a via contact 420 provided in a second insulation layer 400.

In the following, each configuration of the semiconductor storage device is described more specifically.

The semiconductor substrate 100 is a substrate that includes a semiconductor material and on which the capacitor 11 and the transistor 21 are to be formed. The semiconductor substrate 100 may be a silicon substrate, or may be an SOI (Silicon On Insulator) substrate in which an insulation film of, for example, SiO₂ is interposed in a silicon substrate. Further, the semiconductor substrate 100 may be a substrate including another element semiconductor such as that of germanium, or may be a substrate including a compound semiconductor such as gallium arsenide (GaAs), gallium nitride (GaN), or silicon carbide (SiC).

An element isolation layer 105 includes an insulating material and electrically isolates the transistors 21 provided on the semiconductor substrate 100 from one another. For example, the element isolation layer 105 may include an insulating material such as silicon oxide (SiOₓ), silicon nitride (SiNₓ), or silicon oxynitride (SiON).

For example, the element isolation layer 105 is formable, using an STI (Shallow Trench Isolation) method, by removing a portion of the semiconductor substrate 100 in a predetermined region by etching or the like, and thereafter filling an opening formed by etching or the like with silicon oxide (SiOₓ). Alternatively, the element isolation layer 105 may be formed, using a LOCOS (LOCal Oxidation of Silicon) method, by thermally oxidizing the semiconductor substrate 100 in a predetermined region.

The regions isolated from each other by the element isolation layer 105 each serve as an active region in which the transistor 21 is to be provided. For example, a first-conductivity-type impurity (e.g., a p-type impurity such as boron (B) or aluminum (Al)) is introduced into the active region.

The gate electrode 130 includes an electrically conductive material and is provided on the semiconductor substrate 100. For example, the gate electrode 130 may include polysilicon or the like. Further, a surface of the gate electrode 130 is provided with a cap layer 131 including silicide which is an alloy of cobalt (Co) or nickel (Ni) and silicon (Si).

It is to be noted that a gate insulation film including an oxide such as silicon oxide (SiOₓ) may be provided between the gate electrode 130 and the semiconductor substrate 100.

The source or drain region 151 is a region of the second conductivity type formed on the semiconductor substrate 100. Specifically, the source or drain regions 151 are provided on the semiconductor substrate 100 on respective opposite sides of the gate electrode 130. The source side of the source or drain regions 151 is electrically coupled to the capacitor 11 via the source contact 220, and the drain side of the source or drain regions 151 is electrically coupled to the bit line BL via the drain contact 210.

For example, the source or drain regions 151 are formable by introducing a second-conductivity-type impurity (e.g., an n-type impurity such as phosphorus (P) or arsenic (As)) into the semiconductor substrate 100 in the active region 150. It is to be noted that an LDD (Lightly-Doped Drain) region may be formed in the semiconductor substrate 100 between the source or drain regions 151 and the gate electrode 130. The LDD region is lower than the source or drain regions 151 in concentration of the second-conductivity-type impurity.

In addition, a surface of the semiconductor substrate 100 of the source or drain regions 151 is provided with contact regions 152. The contact regions 152 are able to reduce contact resistance between the source or drain regions 151, and the drain contact 210 and the source contact 220. The contact regions 152 may include an alloy of metal such as Co or Ni and silicon (a so-called silicide).

A sidewall insulation film 132 includes an insulating material and is provided as a sidewall on a side surface of the gate electrode 130. The sidewall insulation film 132 is formable by depositing an insulation film uniformly in a region including the gate electrode 130 and thereafter performing vertical anisotropic etching on the insulation film. For example, the sidewall insulation film 132 may be formed as a single layer or a plurality of layers with an insulating oxynitride such as silicon oxide (SiOₓ), silicon nitride (SiNₓ), or silicon oxynitride (SiON).

The sidewall insulation film 132 is able to control a positional relationship between the gate electrode 130 and the source or drain regions 151 in a self-aligning manner by blocking the second-conductivity-type impurity upon introducing the second-conductivity-type impurity into the semiconductor substrate 100. In addition, the sidewall insulation film 132 is able to control the introduction of the second-conductivity-type impurity into the semiconductor substrate 100 in a step-by-step manner. This makes it possible to form the above-described LDD region between the source or drain regions 151 and the gate electrode 130 in a self-aligning manner.

The first interlayer insulation film 200 includes an insulating material and is provided to expand over the entire surface of the semiconductor substrate 100 with the transistor 21 being embedded therein. For example, the first interlayer insulation film 200 may include an insulating oxynitride such as silicon oxide (SiOₓ), silicon nitride (SiNₓ), or silicon oxynitride (SiON).

The second interlayer insulation film 201 includes, for example, silicon oxide (SiOₓ) or silicon nitride (SiNₓ) and is provided on the first interlayer insulation film 200. The second interlayer insulation film 201 is able to prevent the drain contact 210 from being exposed to a cleaning solution or the like and being damaged in a later step in forming the capacitor 11. In a case where the first interlayer insulation film 200 includes silicon oxide (SiOₓ), the second interlayer insulation film 201 may include silicon nitride (SiNₓ). In such a case, the second interlayer insulation film 201 is able to serve as a stopper film upon removing a film or the like deposited on the second interlayer insulation film 201 by polishing or the like.

The drain contact 210 is provided by filling the inside of the opening provided in the first interlayer insulation film 200 with a barrier metal layer 211 and an electrically conductive layer 212. The electrically conductive layer 212 includes tungsten (W), polysilicon (poly-Si), or the like and electrically couples the source or drain region 151 and the first wiring layer 310 to each other. The barrier metal layer 211 includes, for example, Ti, TiN, Ru, or the like. The barrier metal layer 211 covers a surface of the electrically conductive layer 212 to thereby suppress interaction between the electrically conductive layer 212 and the first interlayer insulation film 200. However, the drain contact 210 may have any structure and may include any material as long as the drain contact 210 is able to form an ohmic electrical coupling with a contact region 152 on the surface of the source or drain region 151.

The source contact 220 is provided by filling the inside of the opening provided in the first interlayer insulation film 200 with a barrier metal layer 221 and an electrically conductive layer 222. The electrically conductive layer 222 includes tungsten (W), polysilicon (poly-Si), or the like and electrically couples the source or drain region 151 and the lower electrode 111 to each other. The barrier metal layer 221 includes, for example, Ti, TiN, Ru, or the like. The barrier metal layer 221 covers a surface of the electrically conductive layer 222 to thereby suppress interaction between the electrically conductive layer 222 and the first interlayer insulation film 200. However, the source contact 220 may have any structure and may include any material as long as the source contact 220 is able to form an ohmic electrical coupling with a contact region 152 on the surface of the source or drain region 151.

The capacitor 11 is provided inside an opening 110 provided in the first interlayer insulation film 200 and the second interlayer insulation film 201. Specifically, the opening 110 is provided in a region including the source contact 220 to allow the source contact 220 to project therein. The capacitor 11 is provided to cover the projected upper portion of the source contact 220 and to be along an inside shape of the opening 110. For example, the capacitor 11 may be provided to be contained inside the opening 110 in such a manner that a surface position of the upper electrode 115 substantially coincides with a surface position of the second interlayer insulation film 201.

The capacitor 11 is provided by stacking, in order from the source contact 220 side, the lower electrode 111 including Ti, TiN, or the like; the ferroelectric film 113; and the upper electrode 115 including Ti, TiN, or the like. Specifically, the lower electrode 111 is provided along the inside shape of the opening 110 in which the source contact 220 projects. The ferroelectric film 113 is provided on the lower electrode 111 along the inside shape of the opening 110 in a similar manner. The upper electrode 115 is provided on the ferroelectric film 113 to fill the opening 110.

That is, the capacitor 11 is an embedded-type capacitor in which the lower electrode 111 and the upper electrode 115 are insulated with the ferroelectric film 113 interposed therebetween. In the capacitor 11, the area in which the lower electrode 111 and the upper electrode 115 are opposed to each other in parallel and a fringe component from an electrode end of each of the lower electrode 111 and the upper electrode 115 become the area which is effective as capacitance.

In the semiconductor storage device according to the present embodiment, the capacitor 11 is provided in a three-dimensional structure along the inside shape of the opening 110 that allows the source contact 220 to project therein. Accordingly, the capacitor 11 is able to increase in the area in which the lower electrode 111 and the upper electrode 115 are opposed to each other in parallel. In addition, because the capacitor 11 is provided on the source contact 220, the capacitor 11 is formable inside the opening 110 having an opening diameter that is wide to the extent that the opening 110 does not interfere with the gate electrode 130. As a result, the semiconductor storage device according to the present embodiment makes it possible to increase the area of the capacitor 11 and to thereby further increase the capacitance of the capacitor 11.

It is to be noted that the ferroelectric film 113 may include, for example, hafnium oxide (HfO₂) including silicon (Si), zirconium (Zr), lanthanum (La), niobium (Nb), yttrium (Y), germanium (Ge), scandium (Sc), or the like. Alternatively, the ferroelectric film 113 may include lead zirconate titanate (PZT), bismuth strontium tantalate (SBT), or bismuth lanthanum titanate (BLT).

Provided on the second interlayer insulation film 201 is the first insulation layer 300. Provided on the first insulation layer 300 is the first wiring layer 310 that is electrically coupled to the drain contact 210, and the first wiring layer 320 that is electrically coupled to the upper electrode 115 of the capacitor 11. In addition, the second insulation layer 400 and the third insulation layer 500 may be provided on the first insulation layer 300, and the first wiring layer 320 may be electrically coupled to the second wiring layer 520 provided in the third insulation layer 500 via the via contact 420 provided in the second insulation layer 400.

The first insulation layer 300, the second insulation layer 400, and the third insulation layer 500 may include, for example, silicon oxide (SiOₓ), silicon nitride (SiNₓ), or an insulating oxynitride such as silicon oxynitride (SiON). In addition, the first wiring layer 310, the first wiring layer 320, the via contact 420, and the second wiring layer 520 may include a metal material such as aluminum (Al), or may include a damascene structure of copper (Cu).

FIG. 3 is a schematic diagram illustrating a plan configuration for two memory cells of the semiconductor storage device according to the present embodiment.

As illustrated in FIG. 3, the semiconductor storage device according to the present embodiment includes the active region 150; the gate electrode 130; the drain contact 210; the capacitor 11 including the lower electrode 111, the ferroelectric film 113, and the upper electrode 115; the first wiring layer 310; and the first wiring layer 320 that are provided on the semiconductor substrate 100.

The active region 150 is provided to extend in a first direction in a strip shape. The gate electrode 130 is provided to extend in a second direction orthogonal to the first direction. The drain contact 210 is electrically coupled to a second wiring layer 510 via the first wiring layer 310 and the via contact 410. The second wiring layer 510 serves as the bit line BL. The second wiring layers 510 are each provided to extend in the first direction and are each electrically coupled to the drain contact 210 in the memory cell adjacent thereto. That is, the two respective second wiring layers 510 serve as a bit line TRUE and a bit line BAR.

In order to prevent interference or a short circuit with the gate electrode 130, the capacitor 11 may be provided, for example, in a rectangular shape in which a longitudinal direction is set to a second direction that is an extending direction of the gate electrode 130. The upper electrode 115 of the capacitor 11 is electrically coupled to a third wiring layer 620 via the first wiring layer 320, the unillustrated via contact 420, the unillustrated second wiring layer 520, and the like. The third wiring layer 620 serves as the plate line PL. The third wiring layer 620 is provided to expand into the adjacent memory cell and is also electrically coupled to the upper electrode 115 of the capacitor 11 of the adjacent memory cell. The third wiring layer 620 may be provided, for example, to extend in the second direction.

### (1.3. Manufacturing Method)

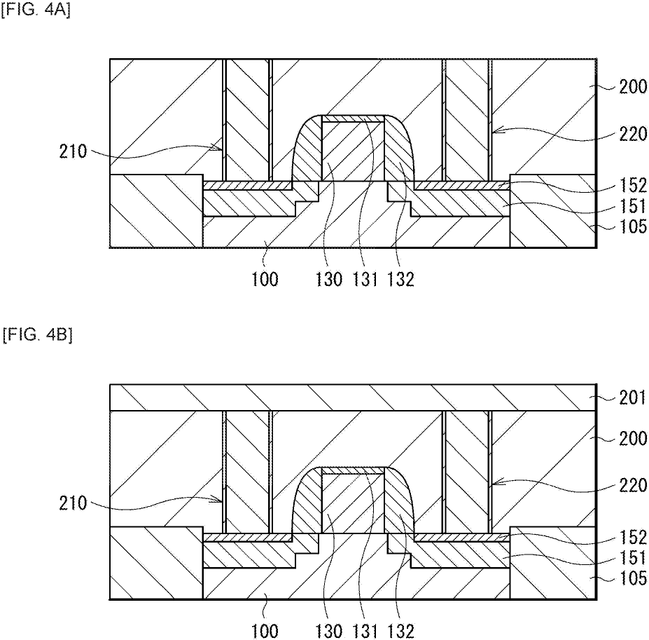

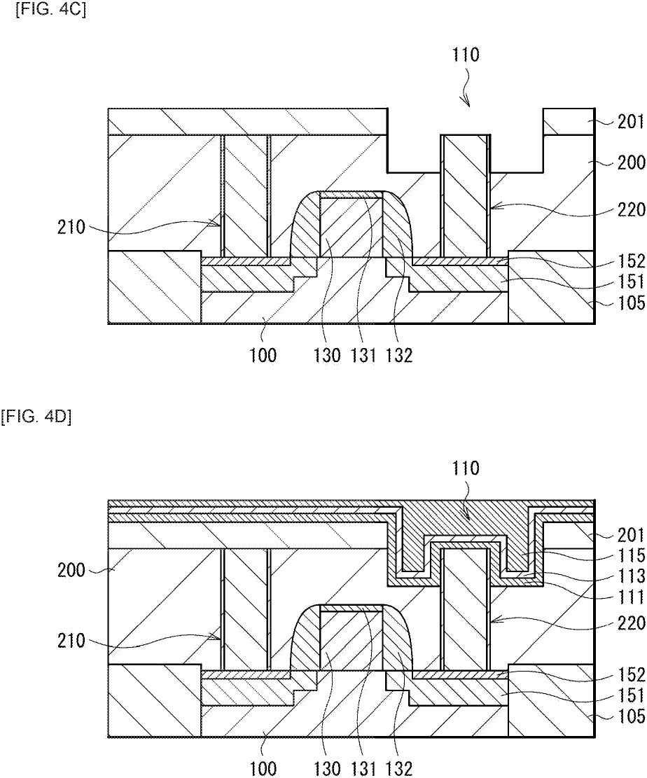

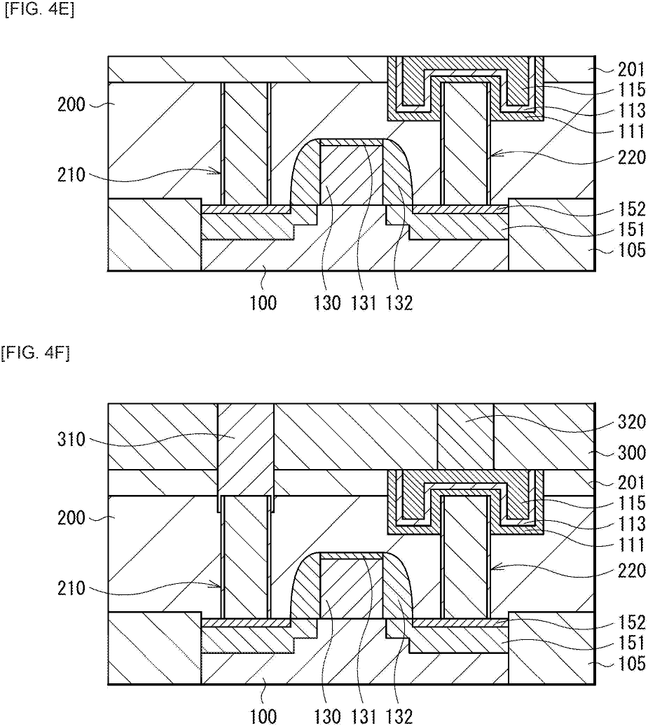

Next, referring to FIGS. 4A to 4F, described is a method of manufacturing the semiconductor storage device according to the present embodiment. FIGS. 4A to 4F are each a cross-sectional view for describing a process of the method of manufacturing the semiconductor storage device according to the present embodiment.

First, as illustrated in FIG. 4A, the transistor 21 is formed on the semiconductor substrate 100 by a publicly-known process. Thereafter, silicon oxide (SiOₓ) is deposited on the semiconductor substrate 100 to thereby deposit the first interlayer insulation film 200 in such a manner as to embed the transistor 21. Thereafter, the drain contact 210 and the source contact 220 running through the first interlayer insulation film 200 are formed to be electrically coupled to the respective source or drain regions 151.

Thereafter, as illustrated in FIG. 4B, silicon nitride (SiNₓ) is deposited on the first interlayer insulation film 200 to thereby form the second interlayer insulation film 201.

Thereafter, as illustrated in FIG. 4C, the first interlayer insulation film 200 and the second interlayer insulation film 201 in a region corresponding to the source contact 220 are removed by etching or the like to thereby form the opening 110. The opening 110 is desirably provided with a spacing of 50 nm with respect to the gate electrode 130 at the closest portion to thereby prevent the gate electrode 130 and the capacitor 11 from being in contact with each other.

Thereafter, as illustrated in FIG. 4D, the lower electrode 111, the ferroelectric film 113, and the upper electrode 115 are uniformly deposited on the second interlayer insulation film 201 having the opening 110.

Thereafter, as illustrated in FIG. 4E, the lower electrode 111, the ferroelectric film 113, and the upper electrode 115 that are deposited on the second interlayer insulation film 201 are removed by polishing or the like. At this time, the second interlayer insulation film 201 including silicon nitride (SiNₓ) is able to serve as a stopper film upon the polishing. It is to be noted that in a case of performing crystallization annealing on the ferroelectric film 113 at 500° C. or higher, it is desirable to perform the crystallization annealing after the process illustrated in FIG. 4D or FIG. 4E.

Thereafter, as illustrated in FIG. 4F, the first insulation layer 300 is deposited on the second interlayer insulation film 201, following which the first wiring layer 310 electrically coupled to the drain contact 210 and the first wiring layer 320 electrically coupled to the upper electrode 115 are formed. It is to be noted that the first wiring layer 310 and the first wiring layer 320 may be provided with respective damascene structures including copper (Cu) as a wiring material. Patterning for forming the first wiring layer 310 and patterning for forming the first wiring layer 320 may be performed together or separately.

With the above-described processes, it is possible to form the semiconductor storage device according to the present embodiment.

The semiconductor storage device according to the present embodiment makes it possible to reduce a manufacturing cost because the number of masks additionally used for lithography is one. Further, the semiconductor storage device according to the present embodiment makes it possible to reduce damage to the ferroelectric film 113 because polishing is used in forming the capacitor 11. Thus, the semiconductor storage device according to the present embodiment makes it possible to suppress a decrease in characteristic of the capacitor 11.

### <2. Second Embodiment>

### (2.1. Configuration Example)

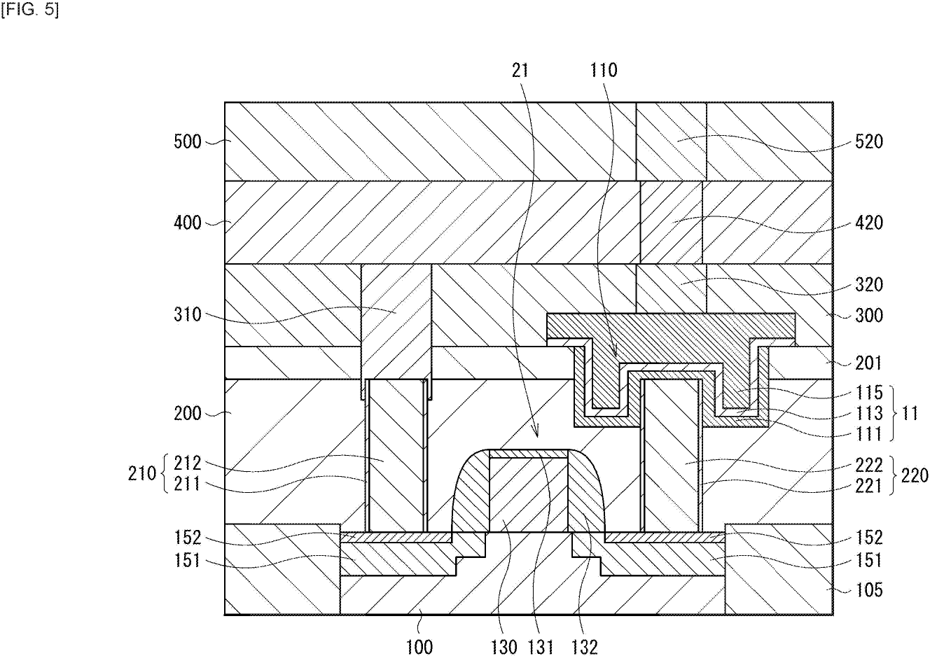

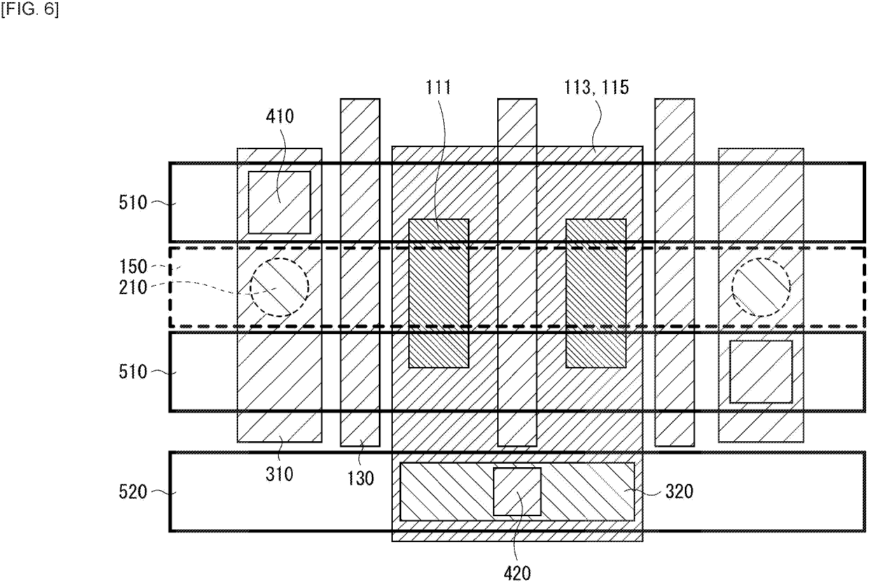

Next, referring to FIGS. 5 and 6, described is a configuration example of a semiconductor storage device according to a second embodiment of the present disclosure. FIG. 5 is a schematic diagram illustrating a cross-sectional configuration of the semiconductor storage device according to the present embodiment. FIG. 6 is a schematic diagram illustrating a plan configuration for two memory cells of the semiconductor storage device according to the present embodiment.

As illustrated in FIG. 5, the semiconductor storage device according to the present embodiment differs from the semiconductor storage device according to the first embodiment in that the ferroelectric film 113 and the upper electrode 115 are deposited and patterned on the second interlayer insulation film 201.

Specifically, the ferroelectric film 113 and the upper electrode 115 deposited on the second interlayer insulation film 201 are patterned and provided to be continuous with the ferroelectric film 113 and the upper electrode 115 of the capacitor 11 of the adjacent memory cell. Thus, the semiconductor storage device according to the present embodiment allows, for example, the ferroelectric film 113 and the upper electrode 115 to be shared between the capacitors 11 of the respective memory cells adjacent to each other.

For example, as illustrated in FIG. 6, the lower electrode 111 is provided to be contained inside the opening 110. The ferroelectric film 113 and the upper electrode 115 expand into the capacitor 11 of the adjacent memory cell, and are provided integrally with the upper electrode 115 of the capacitor 11 of the adjacent memory cell. The upper electrode 115 is electrically coupled to the second wiring layer 520 via the first wiring layer 320 and the via contact 420. The second wiring layer 520 serves as the plate line PL.

The second wiring layer 520 is provided, for example, in the same layer as the second wiring layer 510 electrically coupled to the drain contact 210 via the first wiring layer 310 and the via contact 410. Therefore, the second wiring layer 520 serving as the plate line PL may be provided to extend in the first direction in a manner similar to that of the second wiring layer 510.

It is to be noted that the second wiring layer 520 may be electrically coupled to an unillustrated third wiring layer provided in a further upper layer. In such a case, the third wiring layer may serve as the plate line PL in place of the second wiring layer 520.

### (2.2. Manufacturing Method)

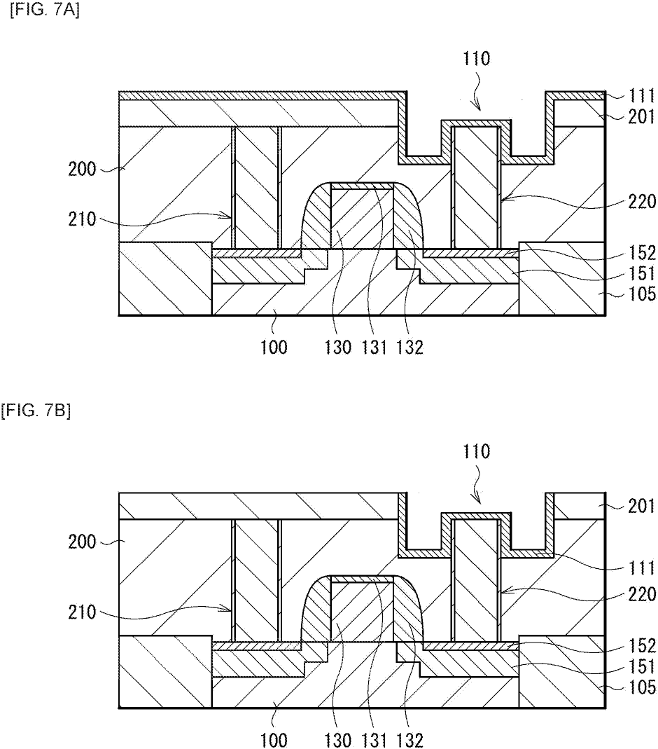

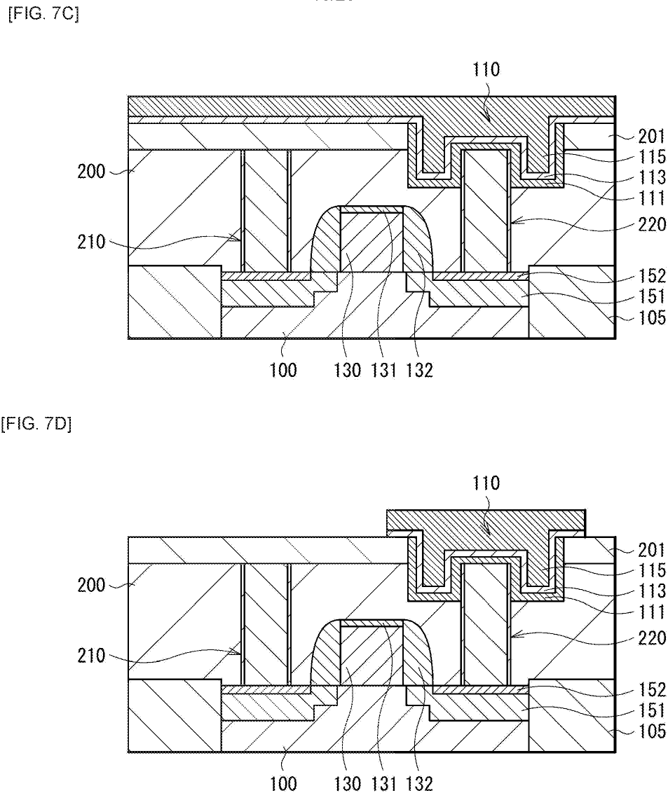

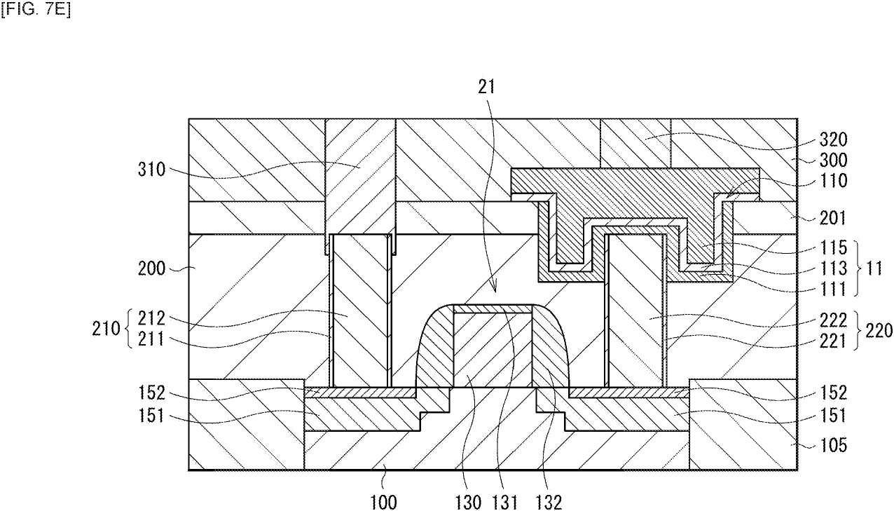

Next, referring to FIGS. 7A to 7E, described is a method of manufacturing the semiconductor storage device according to the present embodiment. FIGS. 7A to 7E are each a cross-sectional view for describing a process of the method of manufacturing the semiconductor storage device according to the present embodiment.

As illustrated in FIG. 7A, the transistor 21, the drain contact 210, and the source contact 220 are formed on the semiconductor substrate 100, and the opening 110 is formed in the first interlayer insulation film 200 and the second interlayer insulation film 201 by processes similar to those illustrated in FIGS. 4A to 4C. Thereafter, an electrically conductive material is deposited inside the opening 110 and on the second interlayer insulation film 201 to thereby form the lower electrode 111.

Thereafter, as illustrated in FIG. 7B, the lower electrode 111 other than that inside the opening 110 is removed by polishing or the like. At this time, the second interlayer insulation film 201 including silicon nitride (SiNₓ) is able to serve as a stopper film upon the polishing.

Thereafter, as illustrated in FIG. 7C, the ferroelectric film 113 and the upper electrode 115 are deposited on the lower electrode 111 and the second interlayer insulation film 201.

Thereafter, as illustrated in FIG. 7D, the ferroelectric film 113 and the upper electrode 115 on the second interlayer insulation film 201 are patterned into a wiring shape.

Thereafter, as illustrated in FIG. 7E, the first insulation layer 300 is deposited on the second interlayer insulation film 201, following which the first wiring layer 310 is formed on the drain contact 210 and the first wiring layer 320 is formed on the upper electrode 115 using respective damascene structures or the like including copper (Cu) as a wiring material.

With the above-described processes, it is possible to form the semiconductor storage device according to the present embodiment.

The semiconductor storage device according to the present embodiment makes it possible to reduce a manufacturing cost because the number of masks additionally used for lithography is two. In addition, the semiconductor storage device according to the present embodiment makes it possible to reduce the possibility of a short circuit between the lower electrode 111 and the upper electrode 115 because the lower electrode 111, the ferroelectric film 113, and the upper electrode 115 are processed separately. In addition, the semiconductor storage device according to the present embodiment makes it possible to improve a degree of freedom in layouts of respective components because the upper electrode 115 is able to be used as a wiring.

### <3. Third Embodiment>

### (3.1. Configuration Example)

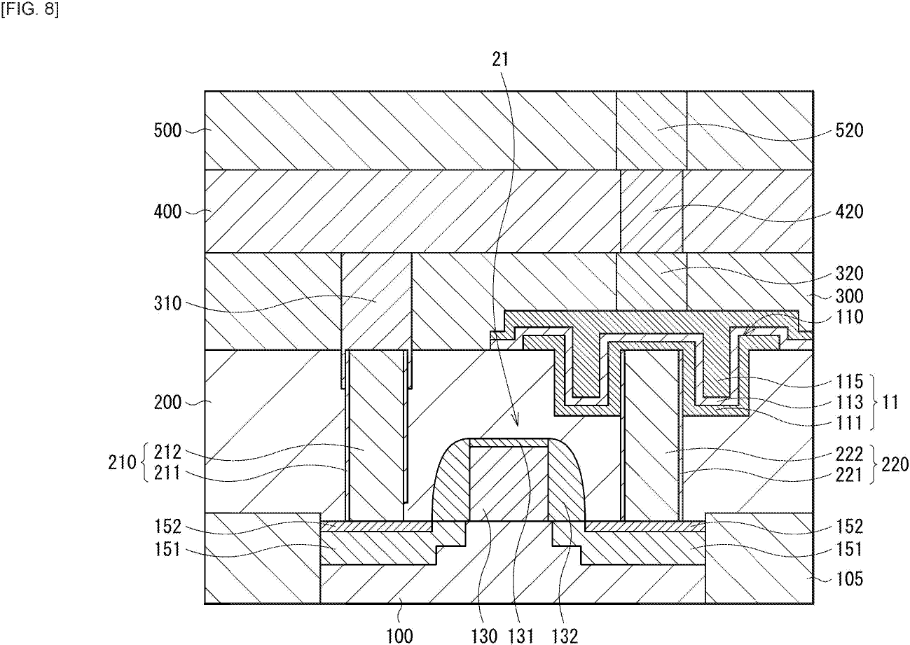

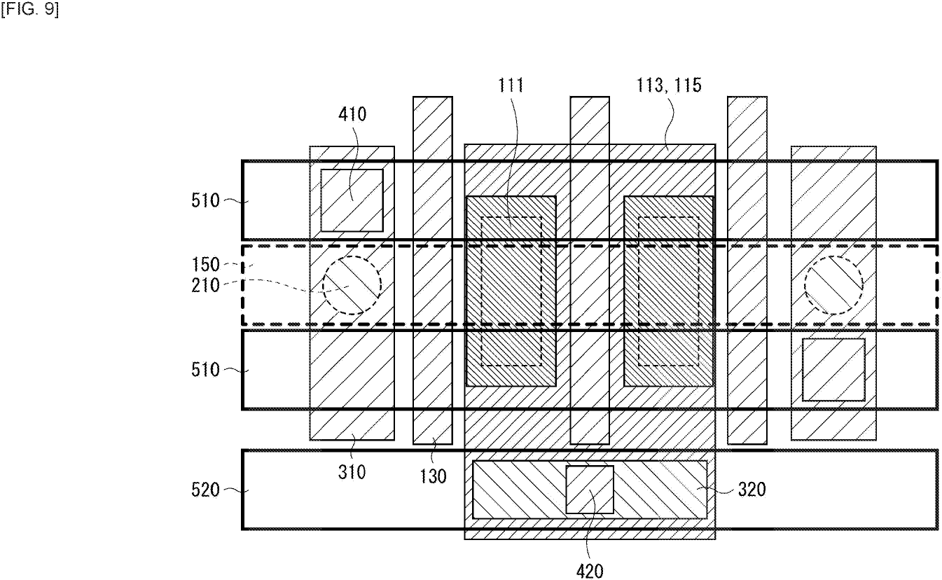

Next, referring to FIGS. 8 and 9, described is a configuration example of a semiconductor storage device according to a third embodiment of the present disclosure. FIG. 8 is a schematic diagram illustrating a cross-sectional configuration of the semiconductor storage device according to the present embodiment. FIG. 9 is a schematic diagram illustrating a plan configuration for two memory cells of the semiconductor storage device according to the present embodiment.

As illustrated in FIG. 8, the semiconductor storage device according to the present embodiment differs from the semiconductor storage device according to the first embodiment in that the lower electrode 111, the ferroelectric film 113, and the upper electrode 115 are deposited and patterned on the first interlayer insulation film 200 and in that the second interlayer insulation film 201 is not provided.

Specifically, the lower electrode 111 deposited on the first interlayer insulation film 200 is provided to be patterned in an island shape in a region including the opening 110. In contrast, the ferroelectric film 113 and the upper electrode 115 deposited on the first interlayer insulation film 200 are patterned and provided to be continuous with the ferroelectric film 113 and the upper electrode 115 of the capacitor 11 of the adjacent memory cell. Thus, the semiconductor storage device according to the present embodiment allows, for example, the ferroelectric film 113 and the upper electrode 115 to be shared between the capacitors 11 of the respective memory cells adjacent to each other.

In addition, in the semiconductor storage device according to the present embodiment, the lower electrode 111, the ferroelectric film 113, and the upper electrode 115 provided outside the opening 110 may be removed by patterning. Therefore, the semiconductor storage device according to the present embodiment does not have to be provided with the second interlayer insulation film 201 serving as a stopper film upon polishing.

For example, as illustrated in FIG. 9, the lower electrode 111 is provided to expand to the outside of the opening 110. The ferroelectric film 113 and the upper electrode 115 expand into the capacitor 11 of the adjacent memory cell, and are provided integrally with the upper electrode 115 of the capacitor 11 of the adjacent memory cell. The upper electrode 115 is electrically coupled to the second wiring layer 520 via the first wiring layer 320 and the via contact 420. The second wiring layer 520 serves as the plate line PL.

The second wiring layer 520 is provided, for example, in the same layer as the second wiring layer 510 electrically coupled to the drain contact 210 via the first wiring layer 310 and the via contact 410. Therefore, the second wiring layer 520 serving as the plate line PL may be provided to extend in the first direction in a manner similar to that of the second wiring layer 510.

It is to be noted that the second wiring layer 520 may be electrically coupled to an unillustrated third wiring layer provided in a further upper layer. In such a case, the third wiring layer may serve as the plate line PL in place of the second wiring layer 520.

### (3.2. Manufacturing Method)

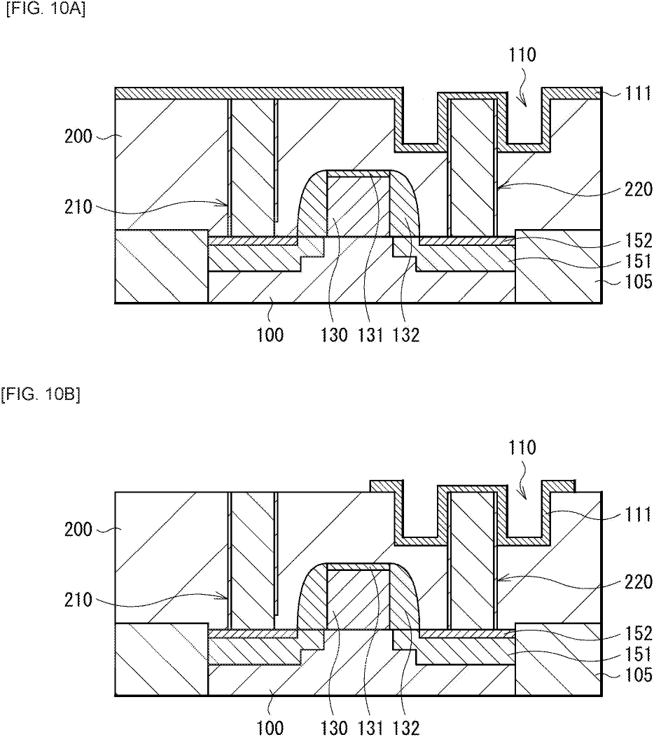

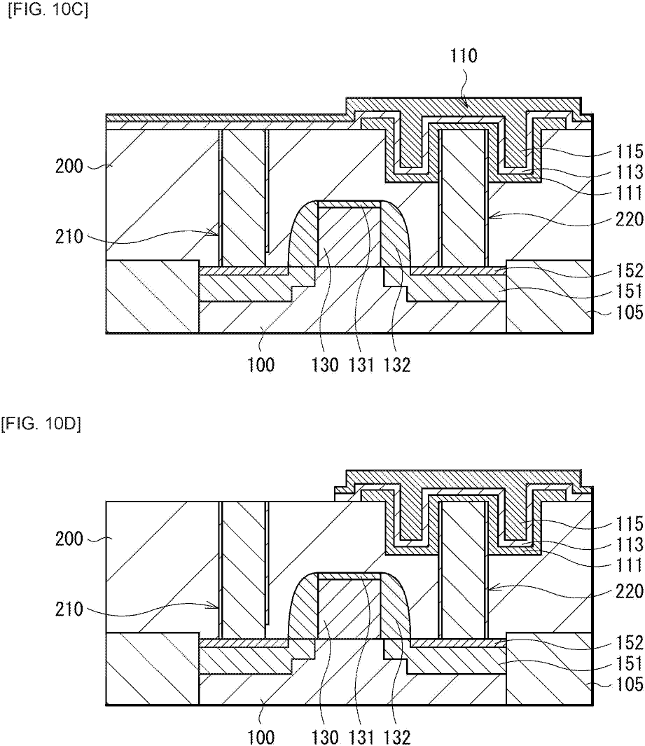

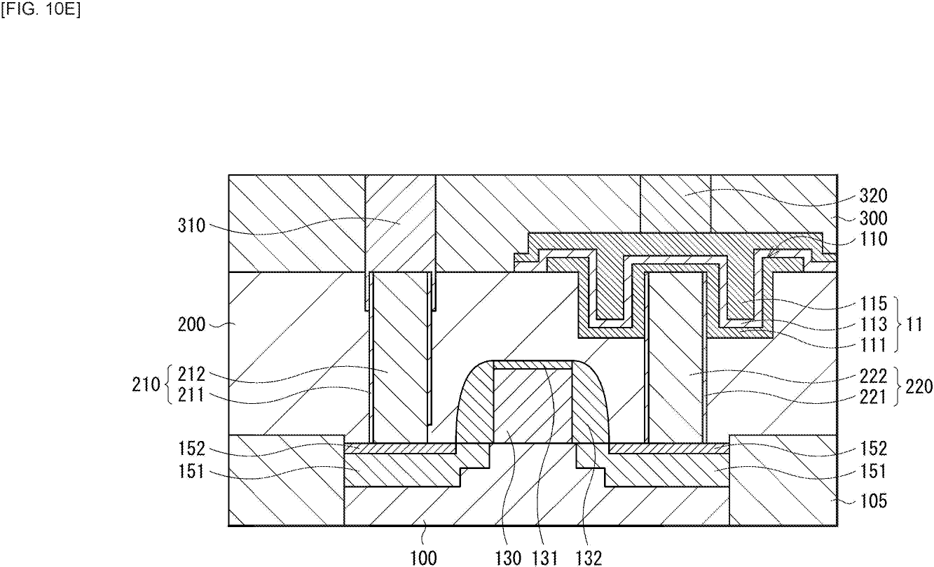

Next, referring to FIGS. 10A to 10E, described is a method of manufacturing the semiconductor storage device according to the present embodiment. FIGS. 10A to 10E are each a cross-sectional view for describing a process of the method of manufacturing the semiconductor storage device according to the present embodiment.

As illustrated in FIG. 10A, the transistor 21, the drain contact 210, and the source contact 220 are formed on the semiconductor substrate 100, and the opening 110 is formed in the first interlayer insulation film 200 in processes similar to those illustrated in FIGS. 4A to 4C. Thereafter, an electrically conductive material is deposited inside the opening 110 and on the first interlayer insulation film 200 to thereby form the lower electrode 111.

Thereafter, as illustrated in FIG. 10B, the lower electrode 111 other than that inside the opening 110 is patterned in the island shape.

Thereafter, as illustrated in FIG. 10C, the ferroelectric film 113 and the upper electrode 115 are deposited on the lower electrode 111 and the first interlayer insulation film 200.

Thereafter, as illustrated in FIG. 10D, the ferroelectric film 113 and the upper electrode 115 on the second interlayer insulation film 201 are patterned into a wiring shape.

Thereafter, as illustrated in FIG. 10E, the first insulation layer 300 is deposited on the second interlayer insulation film 201, following which the first wiring layer 310 is formed on the drain contact 210 and the first wiring layer 320 is formed on the upper electrode 115 using respective damascene structures or the like including copper (Cu) as a wiring material.

With the above-described processes, it is possible to form the semiconductor storage device according to the present embodiment.

The semiconductor storage device according to the present embodiment makes it possible to lower process difficulty and to thereby further suppress variation in manufacturing because polishing is not used to form the capacitor 11. In addition, the semiconductor storage device according to the present embodiment makes it possible to reduce the possibility of a short circuit between the lower electrode 111 and the upper electrode 115 because the lower electrode 111, the ferroelectric film 113, and the upper electrode 115 are processed separately.

### <4. Fourth Embodiment>

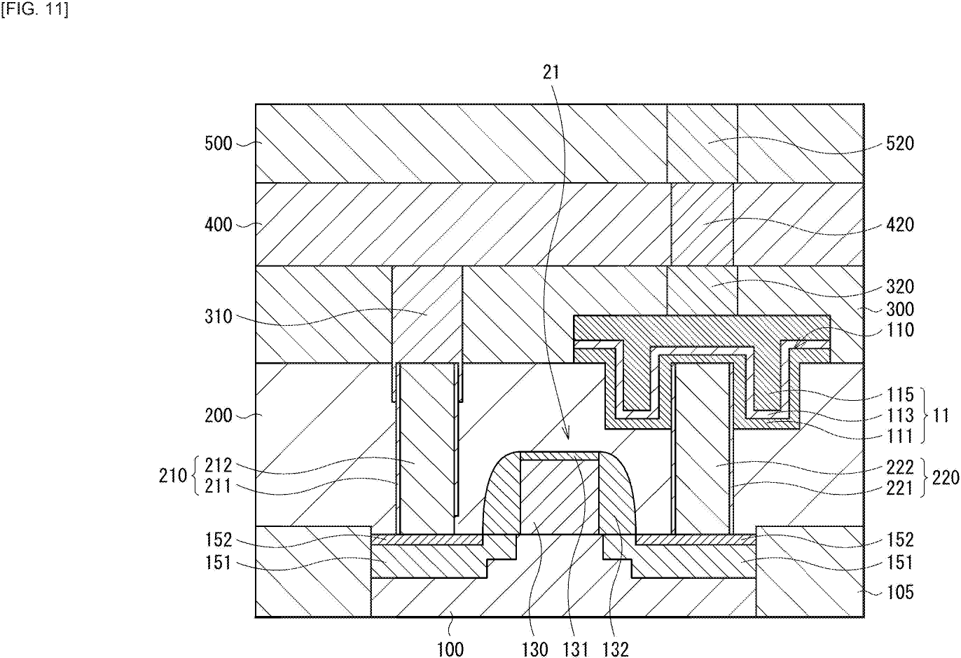

Next, referring to FIG. 11, described is a configuration example of a semiconductor storage device according to a fourth embodiment of the present disclosure. FIG. 11 is a schematic diagram illustrating a cross-sectional configuration of the semiconductor storage device according to the present embodiment.

The semiconductor storage device according to the present embodiment differs from the semiconductor storage device according to the first embodiment in that the lower electrode 111, the ferroelectric film 113, and the upper electrode 115 are deposited and patterned in an island shape on the first interlayer insulation film 200 and in that the second interlayer insulation film 201 is not provided.

Specifically, the lower electrode 111, the ferroelectric film 113, and the upper electrode 115 deposited on the first interlayer insulation film 200 are provided to be patterned in an island shape in a region including the opening 110. In the semiconductor storage device according to the present embodiment, the lower electrode 111, the ferroelectric film 113, and the upper electrode 115 that are provided outside the opening 110 may be removed by the patterning. Therefore, the semiconductor storage device according to the present embodiment does not have to be provided with the second interlayer insulation film 201 serving as a stopper film upon polishing.

The semiconductor storage device according to the present embodiment is formable by sequentially depositing the lower electrode 111, the ferroelectric film 113, and the upper electrode 115 on the first interlayer insulation film 200 provided with the opening 110, and thereafter patterning the lower electrode 111, the ferroelectric film 113, and the upper electrode 115 together.

The semiconductor storage device according to the present embodiment makes it possible to reduce a manufacturing cost because the number of masks additionally used for lithography is two. In addition, the semiconductor storage device according to the present embodiment makes it possible to lower process difficulty and to thereby further suppress variation in manufacturing because polishing is not used to form the capacitor 11.

### <5. Fifth Embodiment>

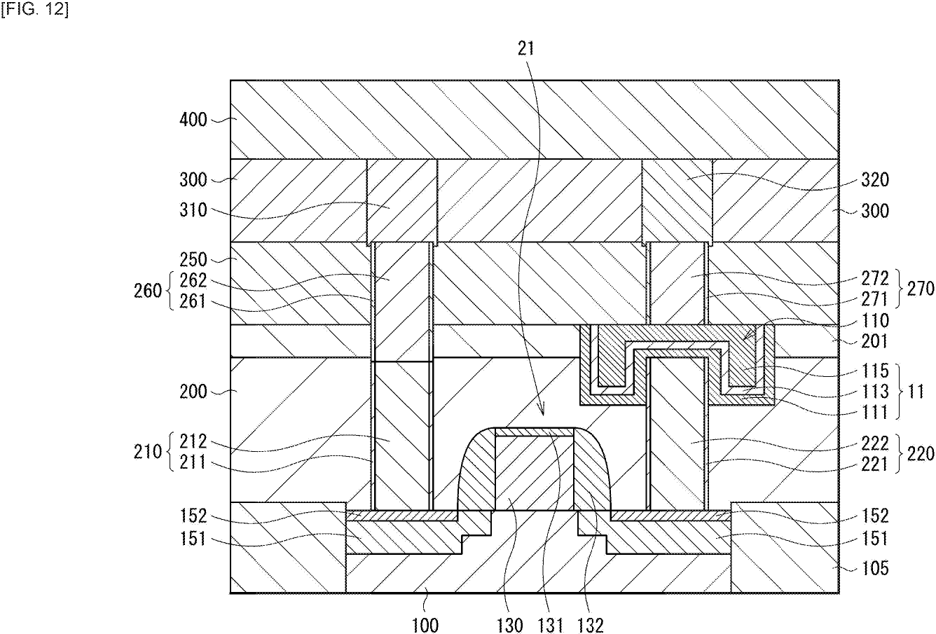

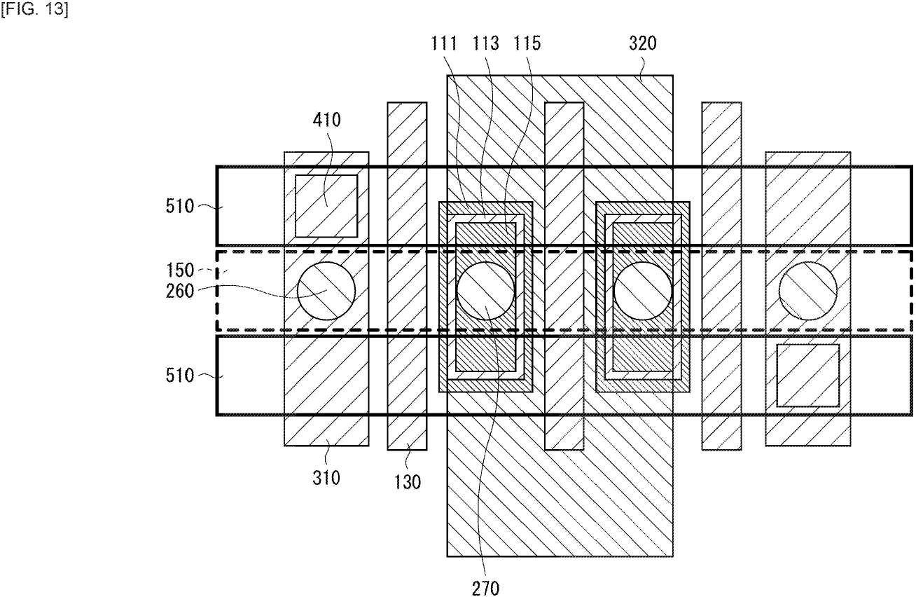

Thereafter, referring to FIGS. 12 and 13, described is a configuration example of a semiconductor storage device according to a fifth embodiment of the present disclosure. FIG. 12 is a schematic diagram illustrating a cross-sectional configuration of the semiconductor storage device according to the present embodiment. FIG. 13 is a schematic diagram illustrating a plan configuration for two memory cells of the semiconductor storage device according to the present embodiment.

As illustrated in FIG. 12, the semiconductor storage device according to the present embodiment differs from the semiconductor storage device according to the first embodiment in that the drain contact 210 and the first wiring layer 310 are electrically coupled to each other via a contact plug 260 and that the upper electrode 115 and the first wiring layer 320 are electrically coupled to each other via a contact plug 270.

Specifically, the contact plug 260 is provided by filling the inside of an opening provided in a third interlayer insulation film 250 with a barrier metal layer 261 and an electrically conductive layer 262. The third interlayer insulation film 250 includes silicon oxide (SiOₓ) or the like. The contact plug 270 is provided by filling the inside of the opening provided in the third interlayer insulation film 250 with a barrier metal layer 271 and an electrically conductive layer 272.

The electrically conductive layers 262 and 272 each include, for example, tungsten (W), polysilicon (poly-Si), or the like. The barrier metal layers 261 and 271 each include, for example, Ti, TiN, Ru, or the like. The barrier metal layers 261 and 271 cover surfaces of the electrically conductive layers 262 and 272, respectively, to thereby suppress interaction between the electrically conductive layers 262 and 272 and the third interlayer insulation film 250, respectively. That is, the contact plugs 260 and 270 may each be provided with a bi-layer structure including an electrically conductive layer and a barrier metal layer similar to that provided for each of the drain contact 210 and the source contact 220.

FIG. 13 is a schematic diagram illustrating a plan configuration for two memory cells of the semiconductor storage device according to the present embodiment.

As illustrated in FIG. 13, the contact plug 270 is provided on the upper electrode 115 of the capacitor 11, and the contact plug 260 is provided on the drain contact 210 (not illustrated).

The contact plug 260 is electrically coupled to the second wiring layer 510 via the first wiring layer 310 and the via contact 410. The second wiring layer 510 serves as the bit line BL. The second wiring layers 510 are each provided to extend in the first direction and are each electrically coupled to the drain contact 210 in the adjacent memory cell. That is, the two respective second wiring layers 510 serve as the bit line TRUE and the bit line BAR.

The contact plug 270 is electrically coupled to the first wiring layer 320 that serves as the plate line PL. The first wiring layer 320 is provided to expand into the adjacent memory cell and is also electrically coupled to the contact plug 270 provided on the upper electrode 115 of the capacitor 11 of the adjacent memory cell. The first wiring layer 320 may be provided, for example, to extend in the second direction.

The semiconductor storage device according to the present embodiment is formable by sequentially performing, after forming the capacitor 11, deposition of the third interlayer insulation film 250, formation of openings in the third interlayer insulation film 250, and formation of the contact plugs 260 and 270 in the respective openings.

The semiconductor storage device according to the present embodiment makes it possible to reduce a manufacturing cost because the number of masks additionally used for lithography is two. Further, the semiconductor storage device according to the present embodiment makes it possible to reduce the number of the wiring layers, due to a high degree of freedom in layout of the first wiring 320.

### <6. Sixth Embodiment>

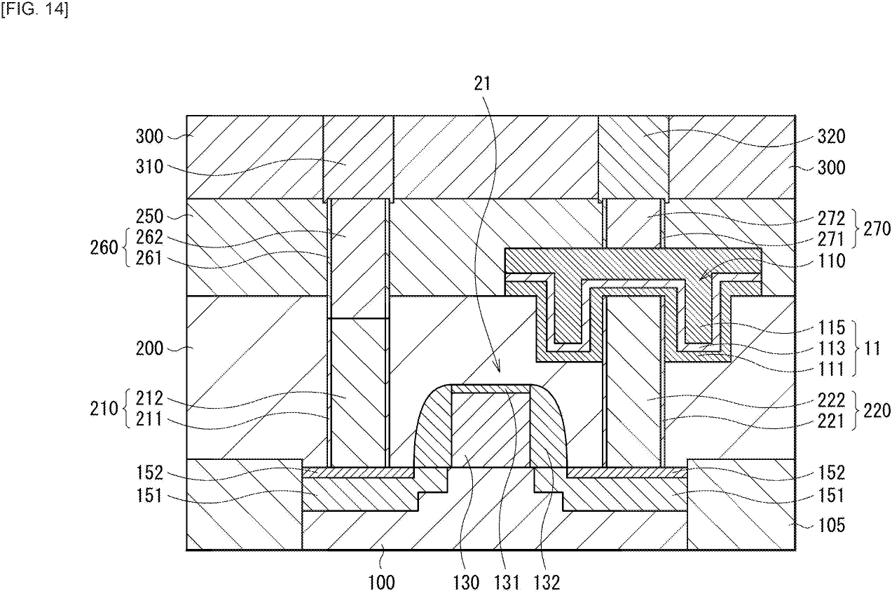

Next, referring to FIG. 14, described is a configuration example of a semiconductor storage device according to a sixth embodiment of the present disclosure. FIG. 14 is a schematic diagram illustrating a cross-sectional configuration of the semiconductor storage device according to the present embodiment.

As illustrated in FIG. 14, the semiconductor storage device according to the present embodiment is a combination of the semiconductor storage device according to the fourth embodiment and the semiconductor storage device according to the fifth embodiment.

Specifically, in the semiconductor storage device according to the present embodiment, the second interlayer insulation film 201 is not provided, and the lower electrode 111, the ferroelectric film 113, and the upper electrode 115 are deposited and patterned in an island shape on the first interlayer insulation film 200. In addition, in the semiconductor storage device according to the present embodiment, the drain contact 210 and the first wiring layer 310 are electrically coupled to each other via the contact plug 260 and the upper electrode 115 and the first wiring layer 320 are electrically coupled to each other via the contact plug 270.

This allows the drain contact 210 to be electrically coupled to the second wiring layer 510 via the contact plug 260, the first wiring layer 310, and the via contact 410, for example. The second wiring layer 510 serves as the bit line BL. In addition, the upper electrode 115 of the capacitor 11 is able to be electrically coupled to the first wiring layer 320 via the contact plug 270, for example. The first wiring layer 320 serves as the plate line PL.

The semiconductor storage device according to the present embodiment makes it possible to lower process difficulty and to thereby further suppress variation in manufacturing because polishing is not used to form the capacitor 11. Further, the semiconductor storage device according to the present embodiment makes it possible to reduce the number of the wiring layers due to a high degree of freedom in layout of the first wiring 320.

### <7. Seventh Embodiment>

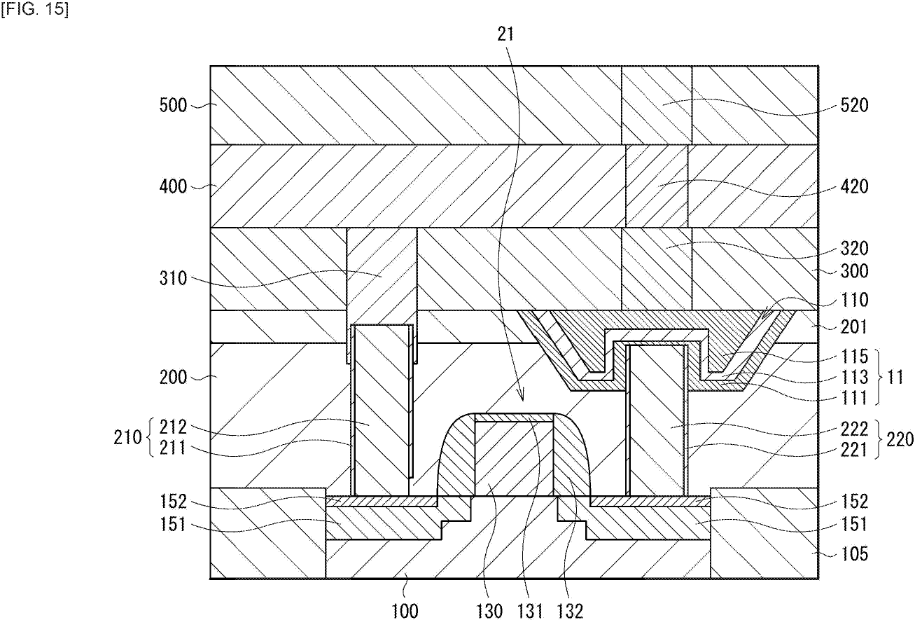

Next, referring to FIG. 15, described is a configuration example of a semiconductor storage device according to a seventh embodiment of the present disclosure. FIG. 15 is a schematic diagram illustrating a cross-sectional configuration of the semiconductor storage device according to the present embodiment.

As illustrated in FIG. 15, the semiconductor storage device according to the present embodiment differs from the semiconductor storage device according to the first embodiment in that the opening 110 for providing the capacitor 11 therein is provided in a tapered shape in which an opening diameter decreases in a direction toward the semiconductor substrate 100.

This allows the opening 110 to be further increased in an opening diameter on the second interlayer insulation film 201 side, making it possible to further increase the capacitance of the capacitor 11. In addition, this allows the opening 110 to be further decreased in an opening diameter on the semiconductor substrate 100 side. This makes it possible to further increase a distance between the lower electrode 111 of the capacitor 11 and the gate electrode 130, thereby making it possible to further suppress the short-circuit between the lower electrode 111 and the gate electrode 130.

The opening 110 having such a tapered shape is formable, for example, by adjusting various conditions, including a kind of gas, a gas flow rate, bias power, and the like for etching of the first interlayer insulation film 200 and the second interlayer insulation film 201.

It is to be noted that the technology according to the seventh embodiment is applicable not only to the semiconductor storage device having the structure illustrated in FIG. 15 but also to a semiconductor storage device having another structure.

The semiconductor storage device according to the present embodiment makes it possible to further increase the capacitance of the capacitor 11 while suppressing the short circuit between the lower electrode 111 and the gate electrode 130.

### <8. Eighth Embodiment>

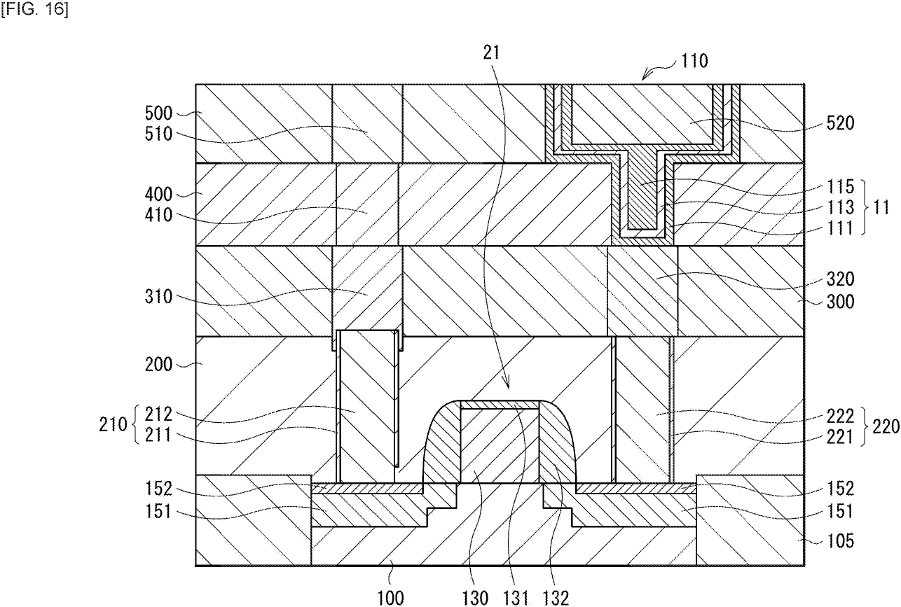

Next, referring to FIG. 16, described is a configuration example of a semiconductor storage device according to an eighth embodiment of the present disclosure. FIG. 16 is a schematic diagram illustrating a cross-sectional configuration of the semiconductor storage device according to the present embodiment.

As illustrated in FIG. 16, the semiconductor storage device according to the present embodiment differs from the semiconductor storage device according to the first embodiment in that the capacitor 11 is provided inside the opening 110 provided in the second insulation layer 400 and the third insulation layer 500, and in that the second interlayer insulation film 201 is not provided.

Specifically, the first wiring layer 320 is provided on the source contact 220, and the opening 110 is provided in the second insulation layer 400 and the third insulation layer 500 provided on the first wiring layer 320. Inside the opening 110, the lower electrode 111 is provided along the inside shape of the opening 110, the ferroelectric film 113 is provided on the lower electrode 111 along the inside shape of the opening 110, and the upper electrode 115 is provided on the ferroelectric film 113. That is, the capacitor 11 may be provided above the source contact 220 with the first wiring layer 320 or the like interposed therebetween, without being in contact with the source contact 220.

For example, this allows the drain contact 210 to be electrically coupled to the bit line BL via the first wiring layer 310, the via contact 410, and the second wiring layer 510, for example. In addition, this allows the upper electrode 115 of the capacitor 11 to be electrically coupled to the plate line PL via the second wiring layer 520, for example.

The semiconductor storage device according to the present embodiment is formable by sequentially depositing the lower electrode 111, the ferroelectric film 113, and the upper electrode 115 on the second insulation layer 400 and the third insulation layer 500 provided with the opening 110, and removing the lower electrode 111, the ferroelectric film 113, and the upper electrode 115 outside the opening 110 by polishing or patterning.

The semiconductor storage device according to the present embodiment allows the capacitor 11 to be formed in the second insulation layer 400 and the third insulation layer 500, therefore making it possible to form the capacitor 11 having a greater area.

### <9. Ninth Embodiment>

### (9.1. Configuration Example)

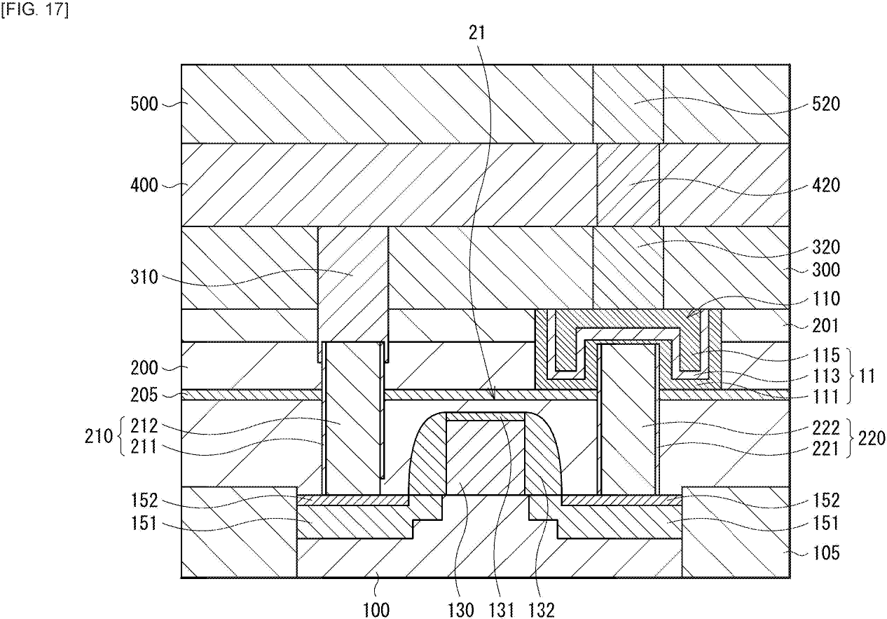

Next, referring to FIG. 17, described is a configuration example of a semiconductor storage device according to a ninth embodiment of the present disclosure. FIG. 17 is a schematic diagram illustrating a cross-sectional configuration of the semiconductor storage device according to the present embodiment.

As illustrated in FIG. 17, the semiconductor storage device according to the present embodiment differs from the semiconductor storage device according to the first embodiment in that a stopper layer 205 is further provided inside the first interlayer insulation film 200.

For example, the stopper layer 205 includes an insulating material that is different from the first interlayer insulation film 200 in etching rate, and is provided in contact with a bottom of the opening 110. For example, in a case where the first interlayer insulation film 200 includes silicon oxide (SiOₓ), the stopper layer 205 may include silicon nitride (SiNₓ). Upon forming the opening 110 in the first interlayer insulation film 200 by etching, the stopper layer 205 is able to stop the etching at the stopper layer 205. This makes it possible to control a formation depth of the opening 110 with high accuracy.

Thus, the stopper layer 205 makes it possible to suppress variation in the formation depth of the opening 110, therefore making it possible to suppress variation in area of the capacitor 11. Accordingly, the semiconductor storage device according to the present embodiment is able to suppress characteristic variation among the memory cells. As a result, the semiconductor storage device according to the present embodiment makes it possible to improve operation stability and to improve reliability.

It is to be noted that the technology according to the ninth embodiment is applicable not only to the semiconductor storage device having the structure illustrated in FIG. 17 but also to the semiconductor storage device having another structure.

### (9.2. Manufacturing Method)

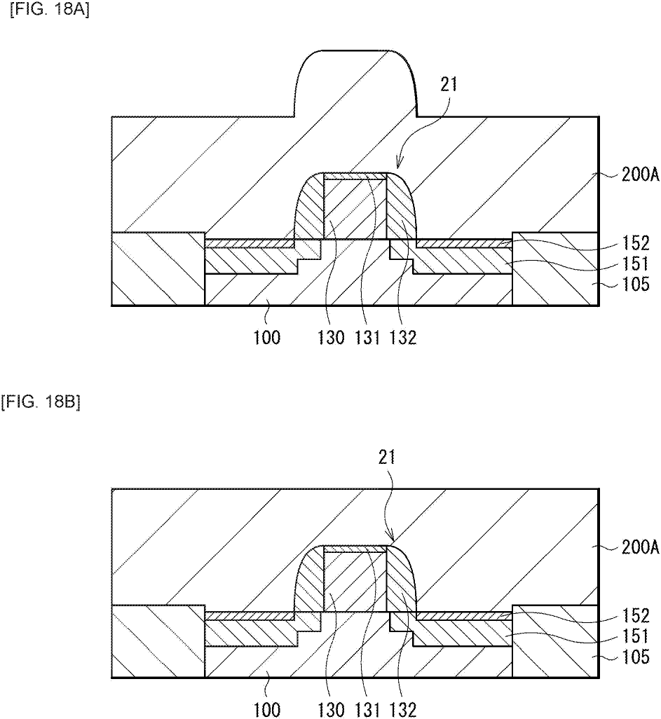

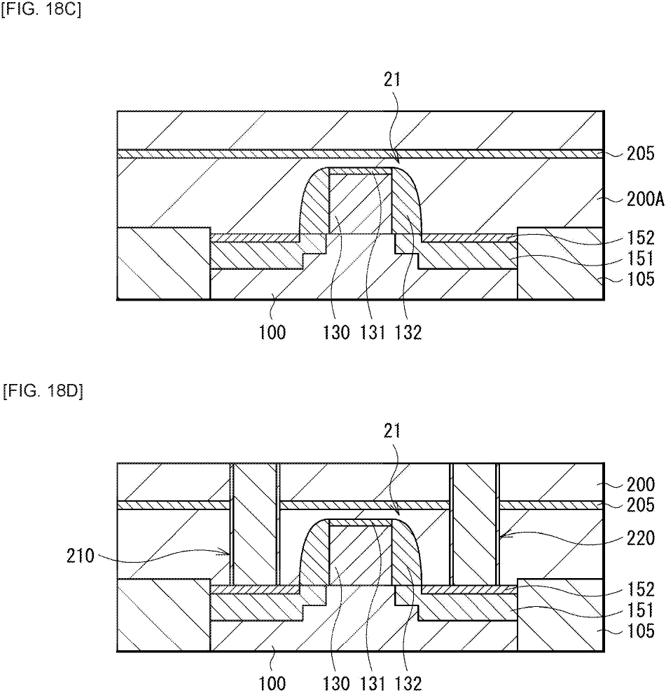

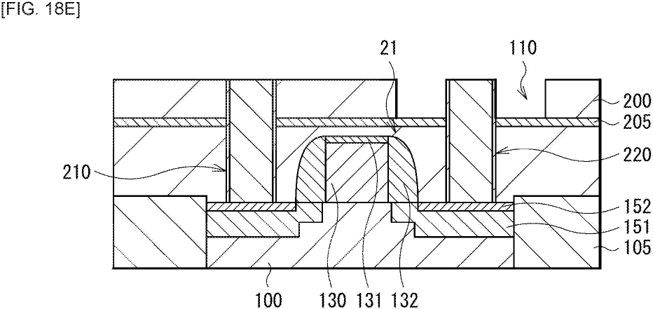

Next, referring to FIGS. 18A to 18E, described is a method of manufacturing the semiconductor storage device according to the present embodiment. FIGS. 18A to 18E are each a cross-sectional view for describing a process of a method of manufacturing the semiconductor storage device according to the present embodiment.

As illustrated in FIG. 18A, the transistor 21 is formed on the semiconductor substrate 100 and a silicon oxide film 200A is deposited to embed the transistor 21 therein.

Thereafter, as illustrated in FIG. 18B, a surface of the silicon oxide film 200A is planarized by CMP or the like.

Thereafter, as illustrated in FIG. 18C, silicon nitride (SiNₓ) is deposited on the silicon oxide film 200A to form the stopper layer 205, and further, silicon oxide is deposited on the stopper layer 205. Thus, it is possible to form the first interlayer insulation film 200 including the stopper layer 205.

Thereafter, as illustrated in FIG. 18D, openings are formed through the first interlayer insulation film 200 including the stopper layer 205 to expose the source or drain regions 151 therefrom, following which the drain contact 210 and the source contact 220 are formed inside the respective openings.

Thereafter, as illustrated in FIG. 18E, a region including the source contact 220 is etched to thereby form the opening 110 in the first interlayer insulation film 200. At this time, because the first interlayer insulation film 200 and the stopper layer 205 differ from each other in etching rate, it is possible to stop the etching at the stopper layer 205.

Thereafter, the lower electrode 111, the ferroelectric film 113, and the upper electrode 115 are sequentially deposited in the opening 110 and are subjected to patterning or the like to form the capacitor 11. Further, forming a wiring having a multilayered structure on the first interlayer insulation film 200 makes it possible to electrically couple the drain contact 210 to the bit line BL and to electrically couple the upper electrode 115 of the capacitor 11 to the plate line PL.

According to the above-described processes, it is possible to form the semiconductor storage device according to the present embodiment.

The semiconductor storage device according to the present embodiment makes it possible to suppress characteristic variation among the memory cells, therefore making it possible to improve operation stability and to improve reliability.

The technology according to the present disclosure has been described above with reference to the first to ninth embodiments. However, the technology according to the present disclosure is not limited to the above-described embodiments and the like and various modifications are possible.

Furthermore, not all the configurations and the operations described in each of the embodiments are essential to the configurations and the operations of the present disclosure. For example, among the components in each of the embodiments, components not described in the independent claims describing the most superordinate concept of the present disclosure should be understood as optional components.

The terms used throughout the specification and the appended claims should be construed as “non-limiting” terms. For example, the terms “include” or “be included” should be construed as “not limited to the example described with the term included”. The term “have” should be construed as “not limited to the example described with the term have”.

The terms used herein include some terms that are used merely for convenience of description and are not used to limit the configuration and the operation. For example, the term such as “right,” “left,” “upper,” or “lower” merely indicates a direction on the referred drawing. Further, the terms “inner” and “outer” merely indicate a direction toward the center of the component of interest and a direction away from the center of the component of interest, respectively. This similarly applies to terms similar to the above-described terms and terms having similar meanings.

It is to be noted that the technology according to the present disclosure is able to have the following configurations. According to the technology of the present disclosure having the following configurations, the semiconductor storage device makes it possible to further increase the area of the capacitor including the ferroelectric film, and to thereby further increase the capacitance of the capacitor including the ferroelectric film. Accordingly, the semiconductor storage device makes it possible to further increase the size of the memory window for distinguishing between the 1-state and the 0-state of stored data, therefore making it possible to further increase operation reliability. Effects exerted by the technology according to the present disclosure are not necessarily limited to the effects described here, and may be any of the effects described in the present disclosure.

A semiconductor storage device including:
a field-effect transistor provided on a semiconductor substrate;
an interlayer insulation film provided on the semiconductor substrate;
a source contact that runs through the interlayer insulation film and is electrically coupled to a source of the field-effect transistor;
an opening that is provided in a region of the interlayer insulation film including the source contact and allows the source contact to project therein; and
a capacitor including a lower electrode, a ferroelectric film, and an upper electrode, the lower electrode being provided along an inside shape of the opening, the ferroelectric film being provided on the lower electrode, the upper electrode being provided on the ferroelectric film to fill the opening.

The semiconductor storage device according to (1) described above, in which
the capacitor is contained inside the opening, and
a surface position of the upper electrode substantially coincides with a surface position of the interlayer insulation film.

The semiconductor storage device according to (1) described above, in which the ferroelectric film and the upper electrode are provided further on the interlayer insulation film.

The semiconductor storage device according to (1) described above, in which the lower electrode, the ferroelectric film, and the upper electrode are provided further on the interlayer insulation film.

The semiconductor storage device according to (3) or (4) described above, in which
the semiconductor storage device includes a memory cell array in which multiple memory cells are arranged, the multiple memory cells each including the field-effect transistor and the capacitor, and
the upper electrode is shared between the memory cells adjacent to each other.

The semiconductor storage device according to any one of (1) to (5) described above, in which
the interlayer insulation film includes a stopper layer including a different material, and
the opening is provided to expose the stopper layer.

The semiconductor storage device according to any one of (1) to (6) described above, in which
a gate electrode of the field-effect transistor is provided to extend in a first direction in a plane of the semiconductor substrate, and
a plan shape of the opening is a rectangular shape in which a longitudinal direction is set to the first direction.

The semiconductor storage device according to any one of (1) to (7) described above, in which the opening is provided in a tapered shape in which an opening diameter decreases in a direction toward the semiconductor substrate.

The semiconductor storage device according to any one of (1) to (8) described above, in which
the upper electrode is electrically coupled to a plate line, and
a drain of the field-effect transistor is electrically coupled to a bit line.

A method of manufacturing a semiconductor storage device, the method including:
forming a field-effect transistor on a semiconductor substrate;
forming an interlayer insulation film on the semiconductor substrate;
forming a source contact that runs through the interlayer insulation film and is electrically coupled to a source of the field-effect transistor;
forming an opening in a region of the interlayer insulation film including the source contact, the opening allowing the source contact to project therein; and
forming a capacitor by stacking a lower electrode and a ferroelectric film along an inside shape of the opening and forming an upper electrode on the ferroelectric film to fill the opening.

This application claims the priority on the basis of Japanese Patent Application No. 2020-101916 filed on Jun. 11, 2020 with Japan Patent Office, the entire contents of which are incorporated in this application by reference.

It should be understood by those skilled in the art that various modifications, combinations, sub-combinations, and alterations may occur depending on design requirements and other factors insofar as they are within the scope of the appended claims or the equivalents thereof.

1. A semiconductor storage device comprising:
a field-effect transistor provided on a semiconductor substrate;
an interlayer insulation film provided on the semiconductor substrate;
a source contact that runs through the interlayer insulation film and is electrically coupled to a source of the field-effect transistor;
an opening that is provided in a region of the interlayer insulation film including the source contact and allows the source contact to project therein; and
a capacitor including a lower electrode, a ferroelectric film, and an upper electrode, the lower electrode being provided along an inside shape of the opening, the ferroelectric film being provided on the lower electrode, the upper electrode being provided on the ferroelectric film to fill the opening.

2. The semiconductor storage device according to claim 1, wherein
the capacitor is contained inside the opening, and
a surface position of the upper electrode substantially coincides with a surface position of the interlayer insulation film.

3. The semiconductor storage device according to claim 1, wherein the ferroelectric film and the upper electrode are provided further on the interlayer insulation film.

4. The semiconductor storage device according to claim 1, wherein the lower electrode, the ferroelectric film, and the upper electrode are provided further on the interlayer insulation film.

5. The semiconductor storage device according to claim 3, wherein
the semiconductor storage device comprises a memory cell array in which multiple memory cells are arranged, the multiple memory cells each including the field-effect transistor and the capacitor, and
the upper electrode is shared between the memory cells adjacent to each other.

6. The semiconductor storage device according to claim 1, wherein
the interlayer insulation film includes a stopper layer including a different material, and
the opening is provided to expose the stopper layer.

7. The semiconductor storage device according to claim 1, wherein
a gate electrode of the field-effect transistor is provided to extend in a first direction in a plane of the semiconductor substrate, and
a plan shape of the opening is a rectangular shape in which a longitudinal direction is set to the first direction.

8. The semiconductor storage device according to claim 1, wherein the opening is provided in a tapered shape in which an opening diameter decreases in a direction toward the semiconductor substrate.

9. The semiconductor storage device according to claim 1, wherein
the upper electrode is electrically coupled to a plate line, and
a drain of the field-effect transistor is electrically coupled to a bit line.

10. A method of manufacturing a semiconductor storage device, the method comprising:
forming a field-effect transistor on a semiconductor substrate;
forming an interlayer insulation film on the semiconductor substrate;
forming a source contact that runs through the interlayer insulation film and is electrically coupled to a source of the field-effect transistor;
forming an opening in a region of the interlayer insulation film including the source contact, the opening allowing the source contact to project therein; and
forming a capacitor by stacking a lower electrode and a ferroelectric film along an inside shape of the opening and forming an upper electrode on the ferroelectric film to fill the opening.
